(19) United States
(12) Patent Application Publication
(10) Pub. No.: US 2025/0105104 A1
(43) Pub. Date: Mar. 27, 2025

(54) QUAD FLAT NO-LEAD PACKAGE WITH ENHANCED CORNER PADS FOR BOARD LEVEL RELIABILITY

(71) Applicant: Texas Instruments Incorporated, Dallas, TX (US)

(72) Inventors: Li Jiang, Allen, TX (US); Rey Javier, Plano, TX (US); Guangxu Li, Allen, TX (US); Enis Tuncer, Dallas, TX (US)

(21) Appl. No.: 18/475,563

(22) Filed: Sep. 27, 2023

(51) Int. Cl. H01L 23/495; H01L 21/56; H01L 23/00; H01L 23/31

(52) U.S. Cl. CPC H01L 23/49541; H01L 21/561; H01L 23/3107; H01L 23/49503; H01L 24/48; H01L 2224/48175

(57) ABSTRACT

An electronic device includes a package structure having four lateral corners, a semiconductor die at least partially enclosed inside the package structure and attached to a die attach pad, conductive leads at least partially exposed outside the package structure along the four lateral sides, a first one of the conductive leads electrically connected to the semiconductor die, an instance of a first conductive feature partially exposed outside the package structure at each of the corners, and an instance of a second conductive feature partially exposed outside the package structure and contacting a respective instance of the first conductive feature at each of the corners, the instance of the second conductive feature exposed outside the package structure along the first side.

### BACKGROUND

Electronic devices can be packaged in a variety of different package structures, such as quad flat no lead (QFN) packages with leads along four lateral sides. Board level reliability (BLR), also referred to as system level reliability can be impacted by thermal effects during fabrication processing, installation in a host system, and in powered operation when soldered to a host printed circuit board (PCB). The device BLR can be impacted by the materials and structure of the package design as well as PCB thickness and coefficient of thermal expansion (CTE) mismatches between lead frame and molding compound materials, with corner pins or leads suffering from the highest thermo-mechanical stresses to interconnect the QFN package and a system PCB. However, many design factors cannot be easily changed and poor BLR performance is often discovered only after lengthy development time.

### SUMMARY

In one aspect, an electronic device includes a package structure with four lateral corners, a semiconductor die at least partially enclosed inside the package structure and attached to a die attach pad, conductive leads at least partially exposed outside the package structure along four lateral sides, a first one of the conductive leads electrically connected to the semiconductor die, an instance of a first conductive feature partially exposed outside the package structure at each of the corners and an instance of a second conductive feature partially exposed outside the package structure along a side and contacting a respective instance of the first conductive feature at each of the corners, the instance of the second conductive feature exposed outside the package structure.

In another aspect, an electronic device includes a package structure with four lateral corners, a semiconductor die at least partially enclosed inside the package structure and attached to a die attach pad, conductive leads at least partially exposed outside the package structure along four lateral sides, a first one of the conductive leads electrically connected to the semiconductor die, an instance of a first conductive feature partially exposed outside the package structure at each of the corners and an instance of a second conductive feature including a conductive film partially exposed outside the package structure along the first side at each of the corners.

In a further aspect, a method of fabricating an electronic device includes providing a conductive metal lead frame with rows and columns of unit areas, each unit area joined to neighboring unit area of an adjacent row or column, each unit area having a die attach pad and four corner areas that include a respective instance of a first conductive feature, and attaching a semiconductor die to the die attach pad in each unit area. The method also includes forming an instance of a package structure that encloses the semiconductor die and has opposite first and second sides, four lateral sides, and four lateral corners in each unit area, forming an instance of a second conductive feature partially exposed outside the first side of the package structure at each of the corners in each unit area, and separating the electronic device from the lead frame.

### BRIEF DESCRIPTION OF THE DRAWINGS

FIG. 1 is a top perspective view of a quad flat no-lead (QFN) electronic device with an enhanced corner pad according to one aspect.

FIG. 1A is a bottom plan view of the electronic device of FIG. 1.

FIG. 1B is a top plan view showing internal details of the electronic device of FIGS. 1 and 1A.

FIG. 1C is a partial sectional side elevation view taken along line 1C-1C of FIG. 1B.

FIG. 2 is a flow diagram showing a method for making an electronic device according to another aspect.

FIGS. 3-10 are views of the electronic device of FIGS. 1-1C undergoing fabrication processing according to an implementation of the method of FIG. 2.

FIG. 11 is a top perspective view of another example QFN electronic device with an enhanced corner pad according to another aspect.

FIG. 11A is a bottom plan view of the electronic device of FIG. 11.

FIG. 11B is a partial sectional side elevation view taken along line 11B-11B of FIG. 11A.

FIG. 11C is a flow diagram showing another example method for making an electronic device according to a further aspect.

FIG. 12 is a bottom plan view of another example QFN electronic device with an enhanced corner pad according to a further aspect.

FIG. 12A is a top plan view of the electronic device of FIG. 12.

FIG. 12B is a partial sectional side elevation view taken along line 12B-12B of FIG. 12A.

FIG. 12C is a flow diagram showing another example method for making an electronic device according to another aspect.

FIG. 13 is a top perspective view of another example QFN electronic device with an enhanced corner pad according to a further aspect.

FIG. 13A is a bottom plan view of the electronic device of FIG. 13.

FIG. 13B is a top plan view of the electronic device of FIGS. 13 and 13A.

FIG. 13C is a partial sectional side elevation view taken along line 13C-13C of FIG. 13B.

FIG. 13D is a flow diagram showing another example method for making an electronic device according to another aspect.

FIG. 14 is a graph of simulated solder joint damage for different pins of modeled QFN electronic devices.

FIG. 14A is a partial top view of a first modeled QFN electronic device having a corner tie bar with no corner pad.

FIG. 14B is a partial top view of a first modeled QFN electronic device having a corner tie bar and a corner pad formed as part of a single lead frame.

FIG. 14C is a partial top view of a first modeled QFN electronic device having a corner tie bar formed as part of a first lead frame and an enhanced corner pad formed as part of a second lead frame.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc. may be referred to herein as first, second, third, etc., such as first and second terminals, first, second, and third, wells, etc., for ease of description in connection with a particular drawing, where such are not to be construed as limiting with respect to the claims. Various disclosed methods and devices of the present disclosure may be beneficially applied to drain extended transistors in an electronic device such as an integrated circuit. While such examples may be expected to provide various improvements, no particular result is a requirement of the present invention unless explicitly recited in a particular claim.

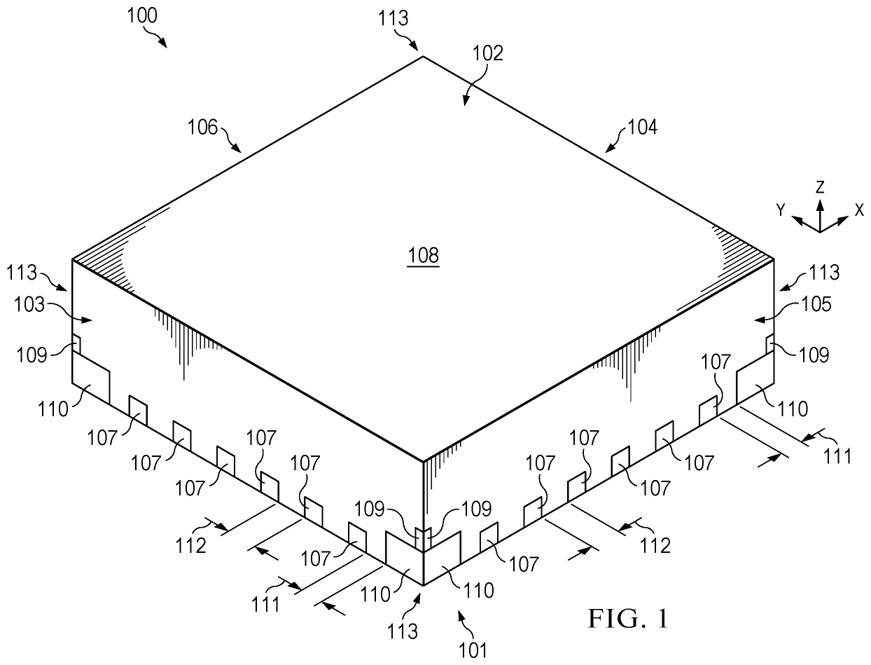

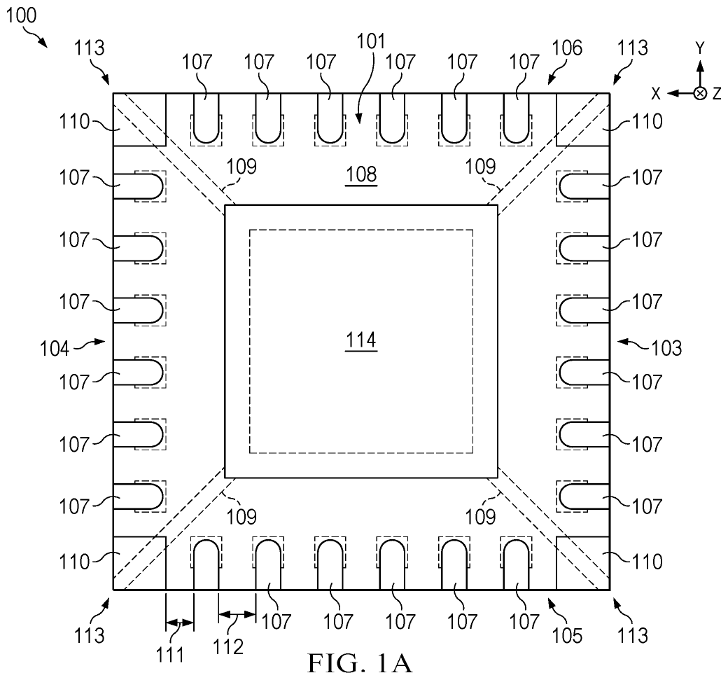

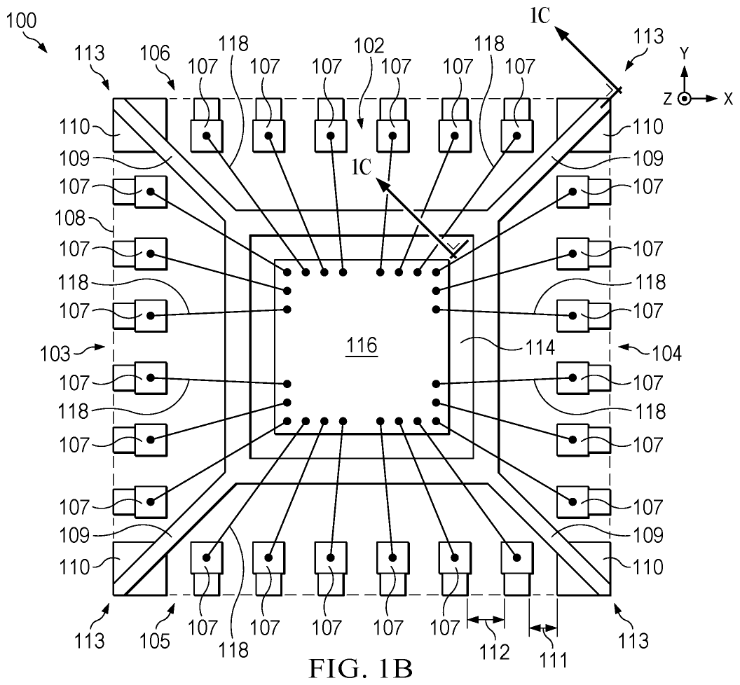

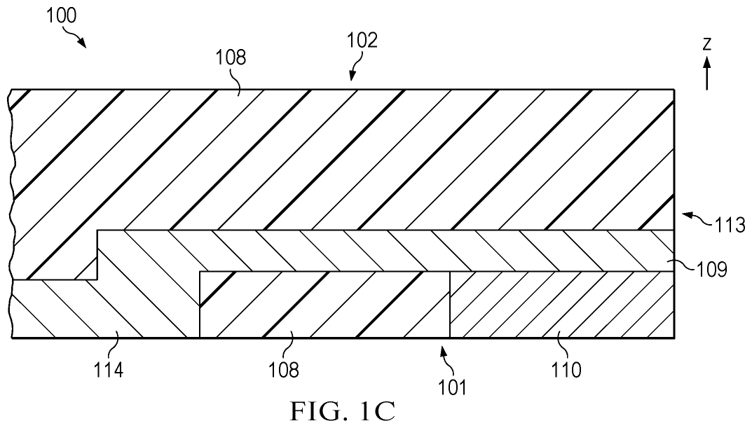

Referring initially to FIGS. 1-1C, FIG. 1 shows a top perspective view of a QFN electronic device 100, FIGS. 1A and 1B show respective bottom and top views, and FIG. 1C shows a side section view of the electronic device 100 taken along line 1C-1C of FIG. 1B. The electronic device 100 includes enhanced corner pads 110 to facilitate improved board and system level reliability. The electronic device 100 is shown in an example position or orientation in a three-dimensional space with a first direction X, a perpendicular (orthogonal) second direction Y, and a third direction Z that is perpendicular (orthogonal) to the respective first and second directions X and Y, and structures or features along any two of these directions are orthogonal to one another.

The electronic device 100 has conductive leads 107 partially exposed along four lateral sides of a package structure 108, such as a molded plastic, and the electronic device has opposite first and second (e.g., bottom and top) sides 101 and 102, respectively, which are spaced apart from one another along the third direction Z as best shown in FIGS. 1 and 1C. The package structure 108 and the electronic device 100 have laterally opposite third and fourth sides 103 and 104 spaced apart from one another along the first direction X, and laterally opposite fifth and sixth sides 105 and 106 spaced apart from one another along the second direction Y (FIGS. 1-1B) in the illustrated orientation. The sides 101-106 in one example have substantially planar outer surfaces. In other examples, one or more of the sides 101-106 have curves, angled features, or other non-planar surface features.

As best shown in FIGS. 1-1B, the conductive leads 107 are at least partially exposed outside each of the four lateral sides 103-106 of the package structure 108. The lateral sides 103-106 form lateral corners 113 of the package structure 108 and of the electronic device 100. The electronic device 100 includes an instance of a first conductive feature 109 partially exposed outside the package structure 108 at each of the corners 113. In addition, the electronic device 100 includes an instance of a second conductive feature 110 partially exposed outside the package structure 108 at each of the corners 113. In the illustrated example, the individual second conductive features 110 contact a respective instance of the first conductive feature 109. The second conductive features 110 are exposed outside the package structure 108 along the bottom or first side 101.

The instances of the second conductive feature 110 at each respective corner 113 are spaced apart from a nearest neighboring one of the conductive leads 107 by a first spacing distance 111 along each respective lateral side 103-106. The adjacent ones of the conductive leads 107 are spaced apart from one another along each respective lateral side 103-106 by a second spacing distance 112, and the first spacing distance 111 is less than the second spacing distance 112.

The electronic device includes a conductive metal die attach pad 114 (FIGS. 1A and 1B). In one example, the first conductive features 109 are conductive metal tie bar features that extend outwardly from and are contiguous with the die attach pad 114, although not a requirement of all possible implementations. The electronic device also includes a semiconductor die 116 at least partially enclosed inside the package structure 108 and attached to the die attach pad 114. As best shown in FIG. 1B, the electronic device includes bond wires 118 providing various electrical interconnections, including electrical connections between one or more of the conductive leads 107 and the semiconductor die 116. In other implementations, different electrical connection structures can be used (e.g., clips, substrates, etc., not shown) alone or in combination with one or more bond wires 118. In the illustrated example, one or more of the bond wires 118 form electrical connections between a corresponding one of the conductive leads 107 and a respective bond pad or other conductive terminal of the semiconductor die 116.

The second conductive feature 110 at each respective corner 113 facilitate good BLR performance of the electronic device 100. The second conductive features 110 are not electrically connected to the leads 107 or the semiconductor die 116 in the electronic device 100. In practice, the second conductive features 110 can be soldered to corresponding pads of a host printed circuit board (not shown) but need not be electrically connected to any circuitry of a host system.

In the illustrated example, the second conductive features 110 are metal pads at the corners 113 that contact portions of the respective tie bar first conductive features 109 and extend from the first conductive feature 109 to the bottom or first side 101 of the electronic device 100. The instance of the second conductive feature 110 at each respective corner 113 is exposed outside the package structure 108 along portions of two respective ones of the lateral sides 103-106 at that respective corner 113.

The instances of the second conductive features 110 beneficially mitigate the adverse effects of CTE mismatch with advanced size and spacing advantages compared with dummy pins or other features of a single starting lead frame. In particular, manufacturing tolerances, such as copper etching processes, can limit the spacing distance 112 between adjacent leads 107 during fabrication of a starting lead frame that includes features ultimately forming the conductive leads 107, the tie bar 109, and the die attach pad 114. Separate fabrication of the second conductive features 110, for example, as a metal pad, allows closer spacing (e.g., the first spacing distance 111 in FIGS. 1-1B) than the second spacing distance 112 between the adjacent conductive leads 107. This provides freedom to enlarge the size of the metal pad second conductive features 110 compared with instead introducing a dummy pad or additional dummy lead in the corners 113 of the starting lead frame.

In the illustrated electronic device 100, for example, the second conductive features 110 are enlarged to mitigate thermal affects and enhance BLR performance by virtue of the lower first spacing distance 111 beyond the size possible for a dummy lead provided in a single starting lead frame. In addition, a dummy lead or dummy pin structure provided in a single starting lead frame can be further limited in thickness along the third direction Z to that of the starting lead frame structure itself, whereas the second conductive features 110 can have a different thickness independent of the starting lead frame design. The reliability improvements of the second conductive features 110 benefit the example leadless wire-bond QFN package structure of the illustrated electronic device 100, and similar benefits can be applied to other forms and shapes of packaged electronic devices. In one example, the size of extra second conductive features 110 (e.g., metal pads) is only limited by surface mount process requirements (e.g., typically 200 μm).

The location of the second conductive features 110 at or near the corners 113 operate as structural anchors to provide particular advantages in mitigating thermal expansion and/or contraction effects on corner or end leads 107 and reduce thermo-mechanical stresses on the end leads 107 as well as interior leads 107 along the lateral sides 103-106 when the electronic device 100 is connected to a host PCB. This allows greater freedom in choice of materials for the package structure 108 (e.g., mold compound) and the conductive metal features thereof (e.g., metals that are or include copper, aluminum, etc.), as well as in the selection of plating or coating materials along portions of the conductive leads 107 and/or the exposed bottom side of the die attach pad 114 to facilitate solder wetting for improved solder connections to a PCB.

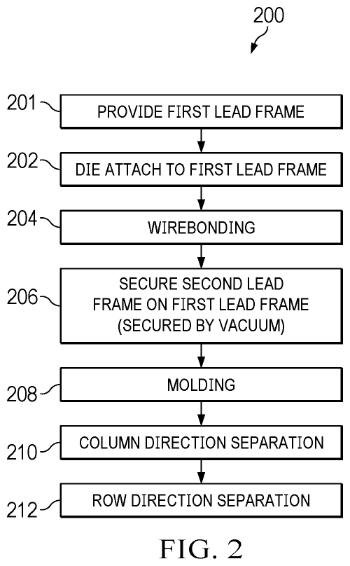

In operation, the provision of the second conductive features 110 at the corners 113 can help enhance BLR performance without changing other design parameters of the electronic device 100, and without delaying product design cycles manufacturing implementation. Also, corner anchor pad size of the second conductive features 110 is not limited by the tie bar dimensions of the first conductive features 109. In particular, the second conductive features 110 can be changed without affecting the design of a starting lead frame, for example, by using a second lead frame including the second conductive features 110 as described further below in connection with FIG. 2. In this regard, the second lead frame can be revised according to BLR performance goals without affecting the design of the first lead frame.

As further shown in the sectional view of FIG. 1C, a first or starting lead frame is used to form the die attach pad 114 in the illustrated example having a thickness of approximately 8 mills, with half etch or thinner features including the contiguous tie bar 109 having a thickness of approximately 4 mills along the third direction Z in the illustrated orientation. The second lead frame used in fabricating the second conductive features 110 in this example has a thickness of approximately 4 mills, although other thicknesses and ranges can be used in different implementations. In the illustrated example, the added second lead frame can have a nominal thickness of 8 mils or more, where thicker corner structures of the electronic device 100 can prevent or mitigate wrinkling of a large lead frame panel array structure and aid in improving BLR performance of the finished electronic device 100.

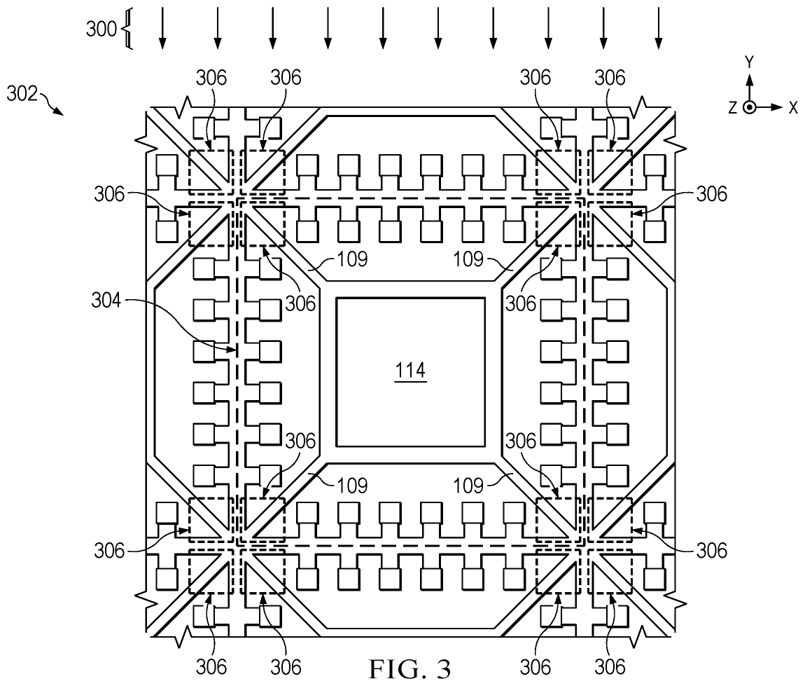

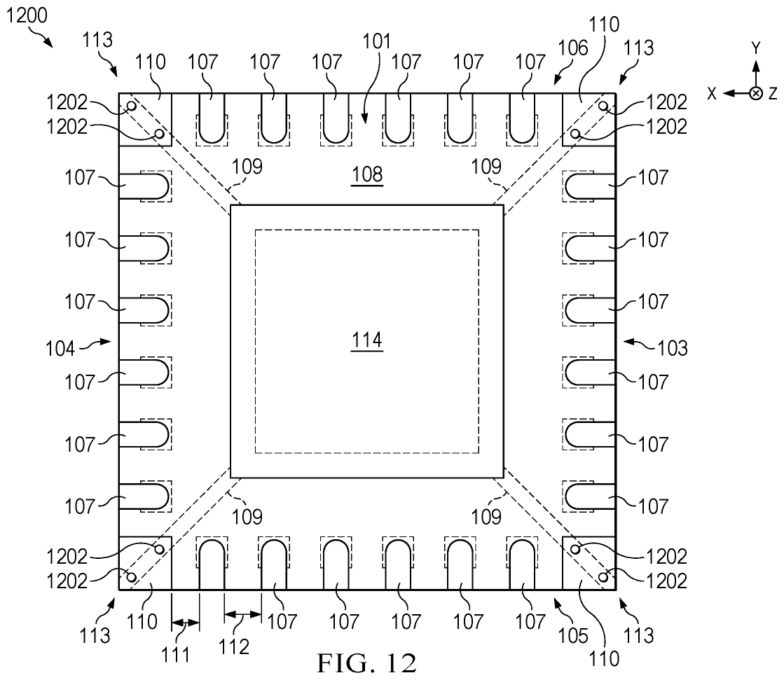

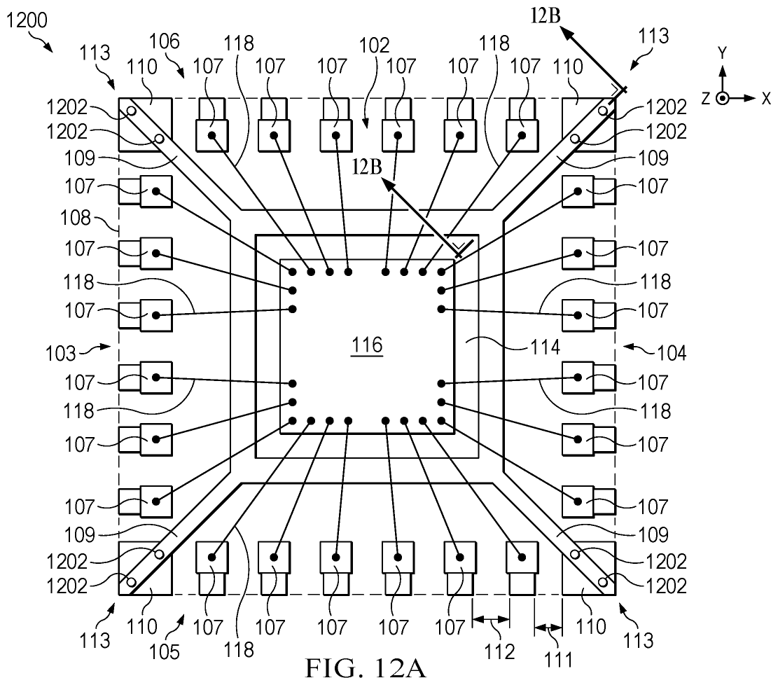

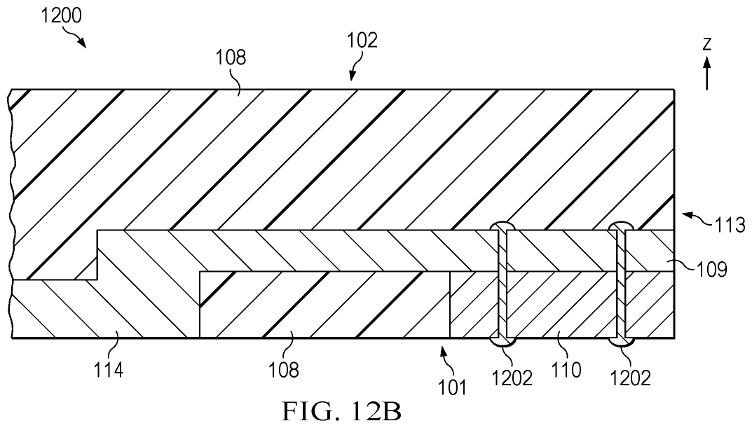

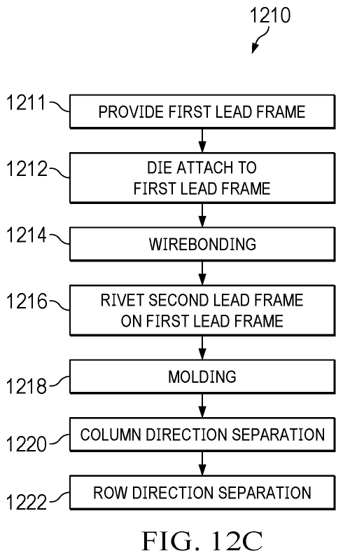

Referring now to FIGS. 2-10, FIG. 2 shows a method 200 for making an electronic device using first and second lead frames, and FIGS. 3-10 are views of the electronic device 100 undergoing fabrication processing according to an implementation of the method 200. The example implementation of the method 200 only adds a single processing step to the packaging assembly and does not require changes for other package assembly processing. In the illustrated example, the second conductive features 110 are held in contact with the first conductive features 109 of their respective lead frames during molding and thereafter remain in a contacting relationship due to the molded package structure 108. In other implementations, the conductive features can be adhered to one another, for example, using rivets (e.g., FIGS. 12-12C below).

The method 200 begins at 201 in FIG. 2 with a provided starting or first lead frame. FIG. 3 shows a portion of an example first lead frame 302 formed as a panel or strip referred to as a lead frame panel array with conductive metal features (e.g., copper, aluminum, etc.) formed in rows and columns by a fabrication process 300, such as stamping, etching, etc. FIG. 3 shows a portion of an example unit area 304 as well as portions of two adjacent or neighboring columns and portions of neighboring rows in an array configuration. The illustrated example has thick and thin portions, for example, thinned by an etch process or other suitable manufacturing steps, with conductive metal features in each unit area 304 corresponding to the leads 107, the tie bars 109 and the die attach pad 114 of the finished electronic device 100 described above. Each unit area 304 is joined to a neighboring unit area 304 of an adjacent row or column. In addition, each unit area 304 has a die attach pad 114 and four corner areas 306 that include a respective instance of the first conductive feature 109 (e.g., a portion of a starting tie bar), with adjacent unit areas initially joined by conductive connections that may be referred to as dam bars, tie bars, etc.

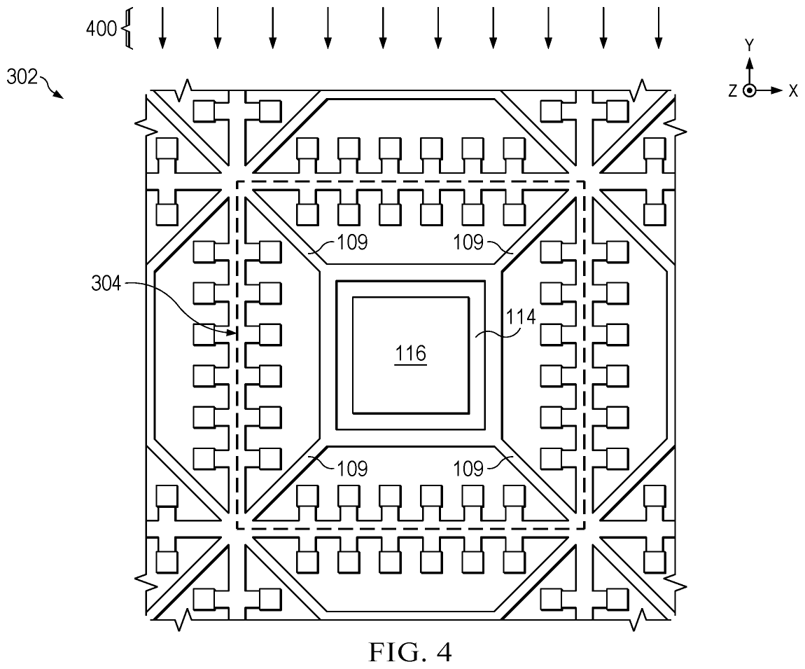

The method 200 includes die attach processing at 202 in FIG. 2, including attaching a semiconductor die 116 to the die attach pad 114 in each unit area 304. FIG. 4 shows one example, in which a die attach process 400 is performed that attaches the semiconductor dies 116 to the die attach pads 114 in each column and row of the lead frame panel array 302. The die attach process 400 can also include attaching other semiconductor dies in one or more unit areas of the lead frame panel array 302, for example, by dispensing, printing, or otherwise providing solder or conductive or nonconductive adhesive in select portions of top sides of certain lead frame features, as well as placement of semiconductor dies and/or passive components in corresponding locations on the solder paste or adhesive (e.g., using automated pick and place equipment, not shown), and subsequent solder reflow and/or curing processing (e.g., thermal reflow, thermal adhesive curing, UV adhesive curing, etc.) to adhere the semiconductor dies to the corresponding locations of the lead frame panel array.

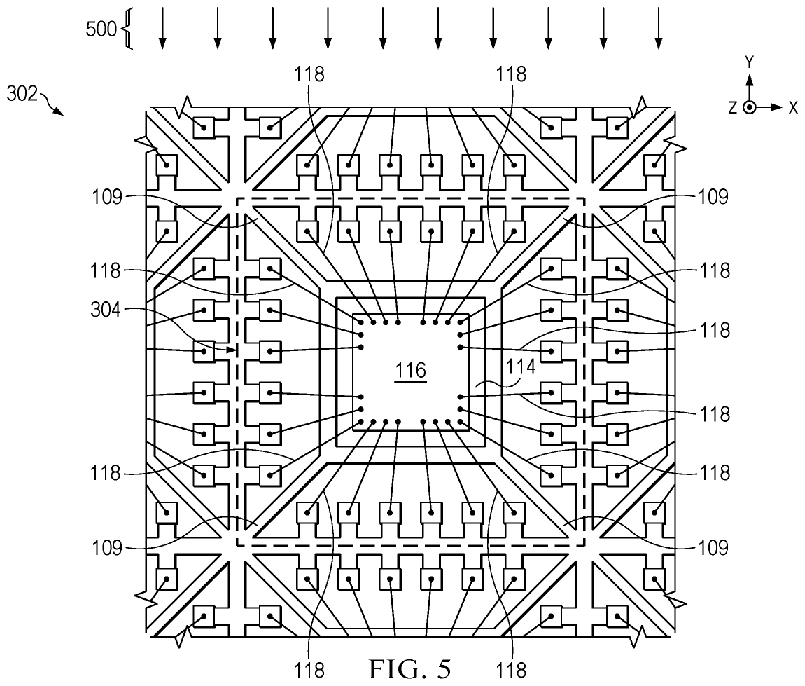

The method 200 continues with wire bonding or other electrical connection processing at 204 in FIG. 2. FIG. 5 shows one example, in which a wire bonding process 500 is performed that creates the bond wires 118 for the electrical circuit connections of the semiconductor die 116 and respective ones of the leads 107 in each unit area 304. In another implementation, further and/or different bond wires (not shown) and/or soldered metal clips (not shown) can be created and/or installed at 204, for example, to provide desired electrical circuit connections in each unit area 304.

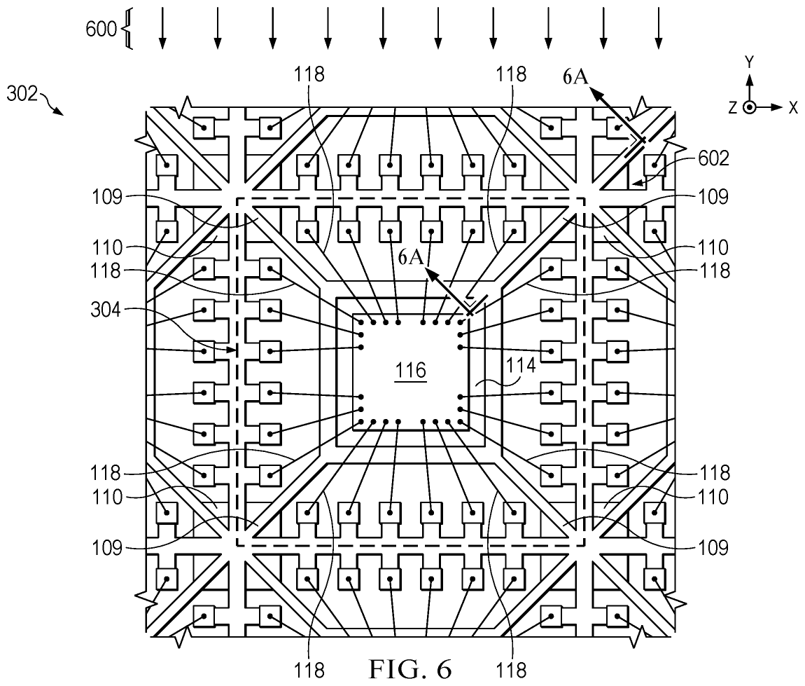

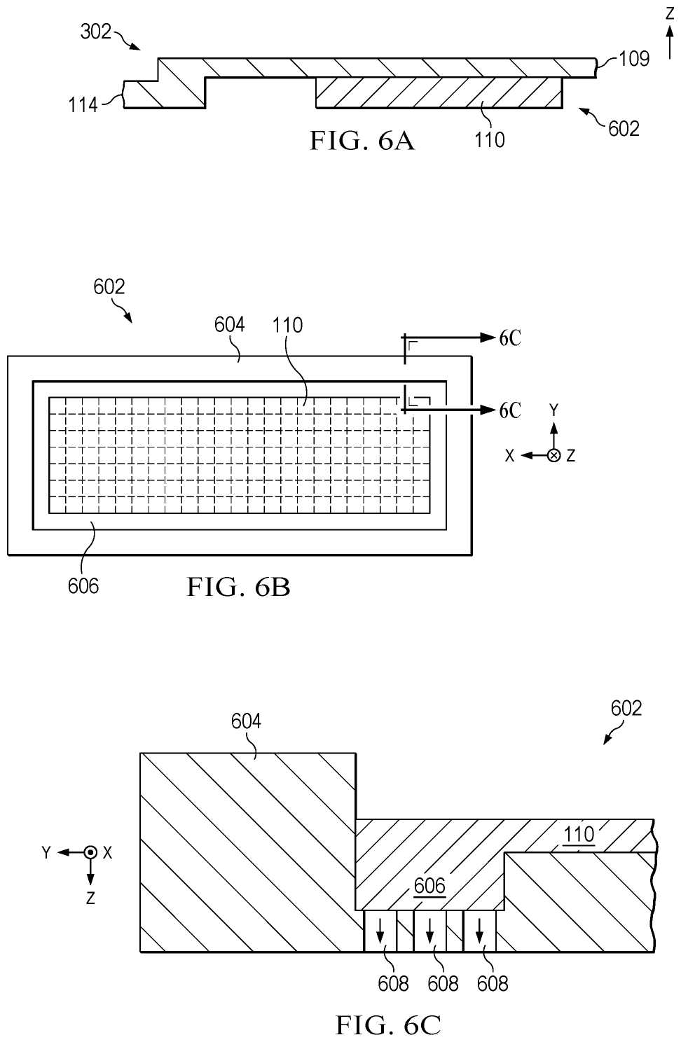

At 206 in FIG. 2, a second lead frame is secured or otherwise attached to (e.g., on) the first lead frame 302. FIG. 6 shows a top view of one example, in which a securing process 600 is performed that secures a second lead frame 602 to the first lead frame 302. In the illustrated example, the second lead frame 602 is installed partially in contact with a back or bottom side of the first lead frame 302 with portions of an instance of a second conductive feature 110 contacting a portion of the tie bar first conductive feature 109 in each corner area 306 in each unit area 304 of the first lead frame 302. FIG. 6A shows a partial sectional side view of the first and second lead frames 302, 602 taken along line 6A-6A in the top view of FIG. 6.

FIG. 6B shows a bottom plan view of the second lead frame 602 having an array configuration with rows and columns of unit areas corresponding to respective unit areas 304 of the first lead frame 302. A fixture 604 in FIGS. 6B and 6C secures the second lead frame 602 to the first lead frame 302 with portions of top sides of the prospective second conductive features 110 in contact with portions of the bottom sides of the respective tie bar first conductive features 109 as shown in FIG. 1A.

FIG. 6C shows a partial sectional side view of the fixture 604 and an edge portion 606 of the second lead frame taken along line 6C-6C of FIG. 6B. As shown in FIG. 6C, the edge portion 606 of the second lead frame 602 in this example is thicker than the interior portions including the prospective second conductive features 110. In the illustrated example, moreover, the fixture 604 includes holes or ports 608 that allow vacuum connection to apply a holding force (e.g., downward in FIG. 6C along the third direction Z) to ensure contact between the prospective first and second conductive features 109 and 110 of the respective lead frames 302 and 602. Attaching the second lead frame 602 to the first lead frame 302 forms the instances of the second conductive feature 110 with the second lead frame 602 having an instance of the second conductive feature 110 contacting each corner area 306 in each unit area 304 of the first lead frame 302 as shown in FIG. 6.

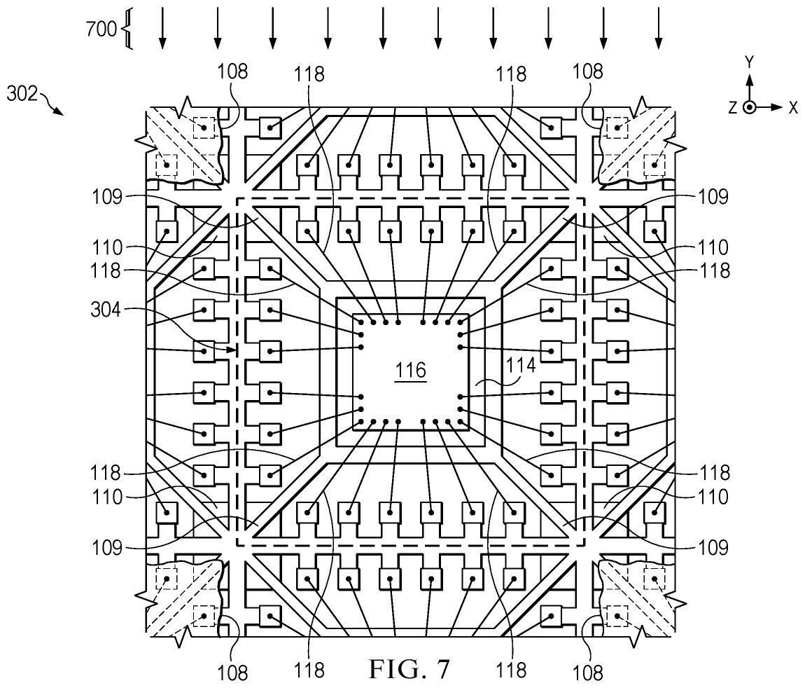

The method 200 continues at 208 in FIG. 2 with molding processing to form the molded package structure 108 along columns and rows of the lead frame panel array 302 and the second lead frame 602. FIG. 7 shows one example, in which a molding process 700 is performed using a mold (not shown). The molded package structure 108 extends over the first conductive features 109 in each unit area 304 and between the first and second lead frames 302 and 602. The package structure 108 encloses the upper portion of the die attach pad 114 (e.g., as shown in FIG. 1C above), and encloses the semiconductor die 116 and the bond wires 118 in each unit area 304 of the array as shown in FIG. 7.

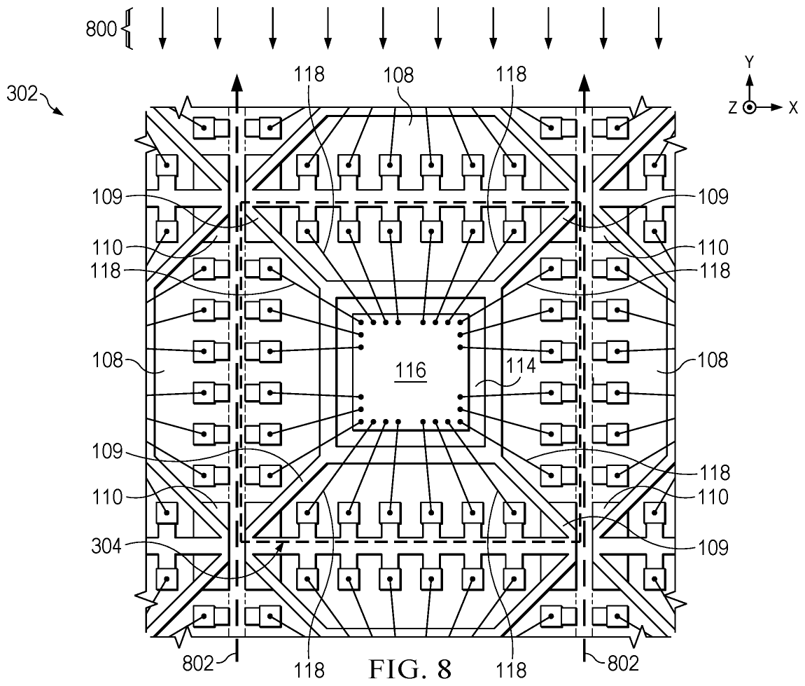

The method 200 continues at 210 with column direction package separation. FIG. 8 shows one example, in which the separation process 800 is performed along the lines 802 (e.g., along the second direction Y in the illustrated orientation) to separate adjacent columns of unit areas 304 from one another. In one example, the separation process 800 is a saw blade cutting operation using one or more cutting blades, such as a single cutting blade performing one cut at a time along the respective lines 802. In another implementation, laser cutting and/or at the separation steps can be used alone or in combination with blade cutting to perform single or multiple pass separation along the lines 802.

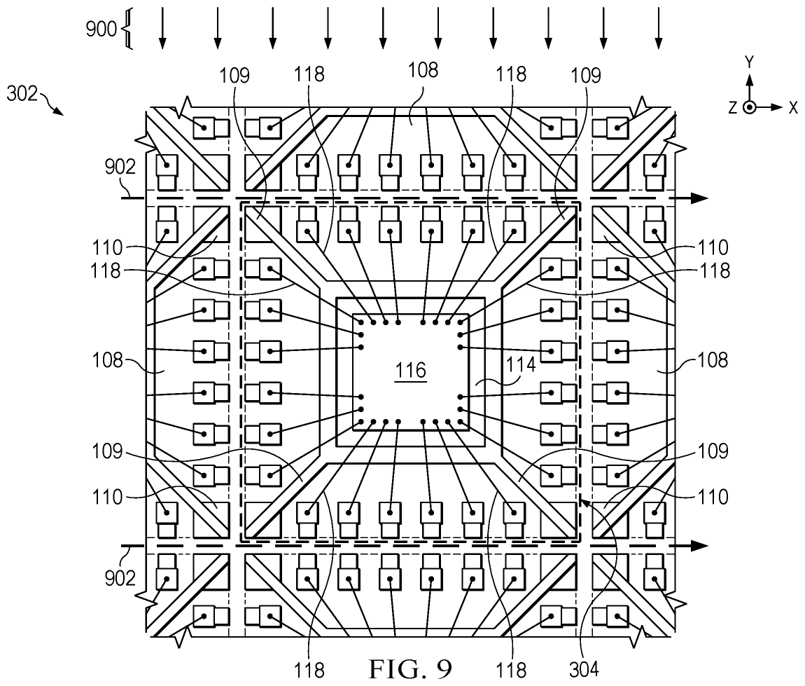

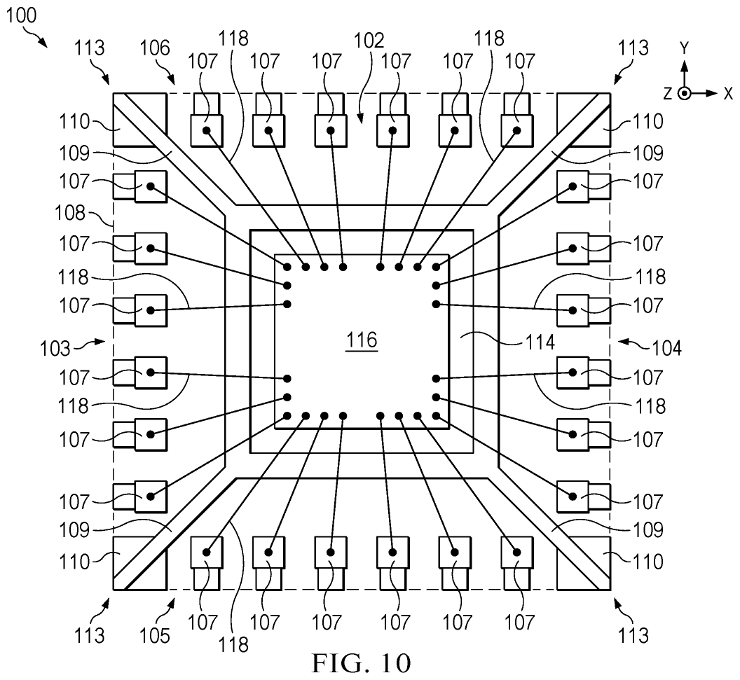

At 212 in FIG. 2, the method 200 includes row direction separation to separate individual packaged electronic devices 100 from one another along each column in the array. FIG. 9 shows one example, in which a separation process 900 is performed (e.g., saw blade cutting, laser cutting, chemical etching, combinations thereof, etc.). The separation process 900 separates adjacent rows from one another along lines 902 shown in FIG. 9. FIG. 10 shows the resulting packaged electronic device 100, in this case a QFN device with conductive leads extending along the cut sidewalls 103-106 created by the separation processes 800 and 900. The molding and separation processing at 208-212 forms an instance of the package structure 108 that encloses the semiconductor die 116 and has opposite (e.g., bottom and top) first and second sides 101, 102, the four lateral sides 103-106, and the four lateral corners 113 in each unit area 304 of the starting array arrangement and separates the packaged electronic device from the starting first lead frame 302. The separation processing at 210 and 212, moreover, cuts through the molded package structure and the conductive features of the first and second lead frames 302 and 602 in the areas between adjacent unit areas 304, referred to as saw streets along the respective lines 802 and 902 of FIGS. 8 and 9, where the addition of the second lead frame 602 does not alter or change the separation processing.

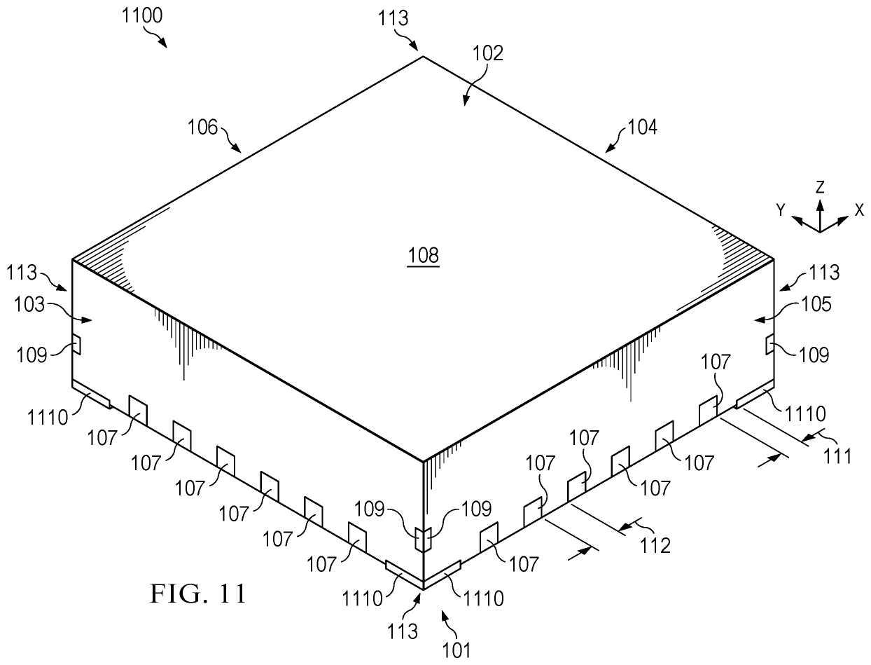

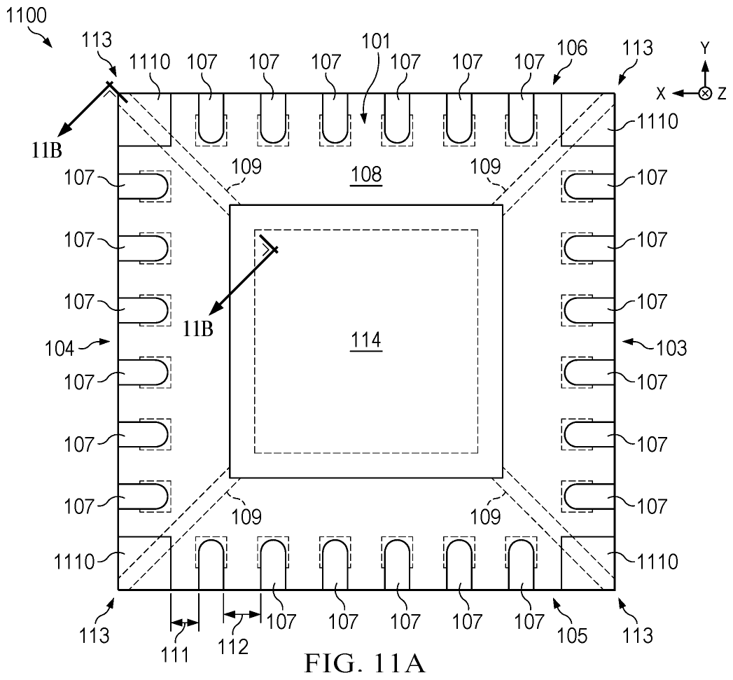

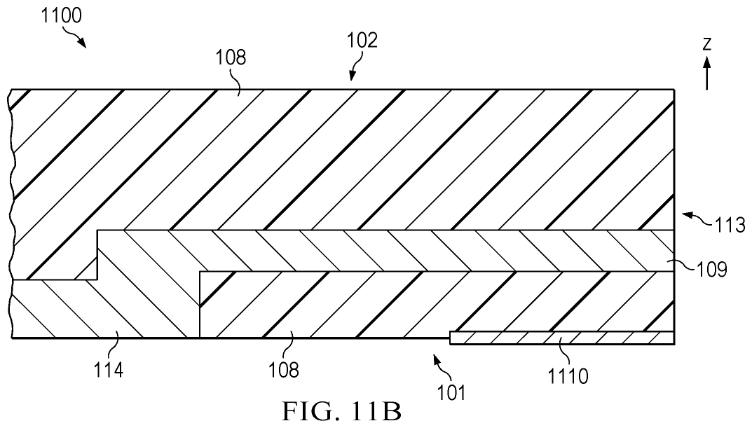

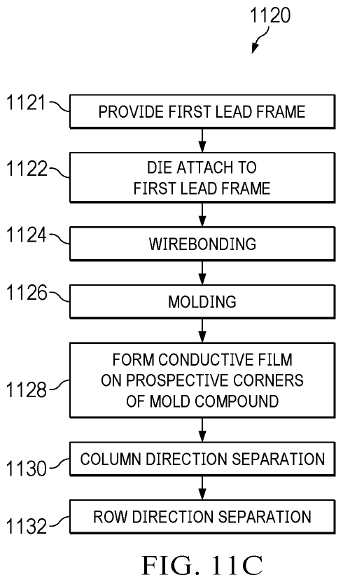

Referring also to FIGS. 11-11C, FIGS. 11-11B show another example QFN electronic device 1100 and FIG. 11C shows an example method 1120 for fabricating an electronic device. The electronic device 1100 in FIGS. 11-11B includes structures, features, and dimensions 101-109 and 111-114 corresponding to those described above in connection with FIGS. 1-1C, and additionally includes a semiconductor die and one or more bond wires (e.g., 116 and 118 above, not shown in FIGS. 11-11C) forming electrical connections between the semiconductor die and the leads. In this example, the electronic device 1100 includes first conductive features 109 at the corners 113, for example, tie bars that extend to and are contiguous with the die attach pad 114, and second conductive features 1110 to provide an enhanced corner pad structure to facilitate good board level reliability.

As described above, an instance of the first conductive feature 109 in the electronic device 1100 is partially exposed outside the package structure 108 at each of the corners 113. In the example electronic device 1100 of FIGS. 11-11B, an instance of a second conductive feature 1110 includes a conductive film partially exposed outside the package structure 108 along the bottom or first side 101 at each of the corners 113.

FIG. 11C shows another example method 1120 for making an electronic device such as the electronic device 1100. The method 1120 includes providing a first lead frame at 1121, such as the above described first lead frame 302 in FIG. 3. At 1122, die attach processing is performed, for example, to attach the semiconductor die 116 to the die attach pad 114 in each unit area 304 of the starting first lead frame 302 (e.g., FIG. 4 above). The method 1120 also includes wire bonding or other electrical connection processing at 1124, for example, to form the bond wires 118 to interconnect the semiconductor die 116 with one or more of the conductive leads 107 in each unit area 304 of the first lead frame panel array 302 (e.g., FIG. 5 above). A molding process is performed at 1126 in FIG. 11C to form the molded package structure (e.g., 108 in FIG. 7 above).

The method 1120 of FIG. 11C also includes forming the instances of the second conductive feature 1110 in corner areas of each unit area of the panel array at 1128. The second conductive features 1110 are created at 1128 by forming a conductive film on the bottom or first side 101 of the package structure 108 near the lateral corners 113 in each unit area 304. In one example, the conductive film is formed at 1128 by a coating process (not shown). In another example, a deposition process can be used, such as sputtering, etc. In a further example, a plating process can be used to form the second conductive features 1110 as a conductive film at 1128. The conductive film formation in these examples advantageously allows the sizing and position of the second conductive feature are not restricted by lead frame fabrication process limitations, for example, to facilitate good board level reliability of the finished electronic device 1100. The instances of the second conductive feature 1110 in the electronic device 1100 at each respective corner 113 are spaced apart from a nearest neighboring one of the conductive leads 107 by the first spacing distance 111 (e.g., FIGS. 11 and 11A) along each respective lateral side 103-106. The adjacent ones of the conductive leads 107 are spaced apart from one another along each respective lateral side 103-106 by a second spacing distance 112, and the first spacing distance 111 is less than the second spacing distance 112.

In one implementation example, the molding process at 1126 in FIG. 11C provides a generally planar bottom or first side 101, which can be substantially or proximately flush with the bottoms of the conductive leads 107 and the exposed bottom side of the die attach pad 114 (e.g., FIG. 11B). In this example, the conductive film that forms the second conductive features 1110 can be deposited to any suitable thickness to accommodate good board level reliability, and the bottom side of the second conductive features can extend beyond the first side 101 of the electronic device 1100.

In another example, the molding at 1126 uses a mold with a slightly raised feature near the corners of the individual unit areas 304 of the lead frame panel array 302 to create a molded package structure 108 having slightly indented corners (e.g., not strictly planar with the bottom side 101), and the conductive film formation at 1128 in FIG. 11C forms the conductive film such that the bottom sides of the second conductive features 1110 are approximately coplanar with the bottom or first side 101 of the finished electronic device 1100.

The method 1120 in FIG. 11C continues at 1130 and 1132 with column and row direction separation processing, respectively. In one example, the separation processing at 1130 and 1132 is the same as the processing at 210 and 212 in FIG. 2 as described above (e.g., FIGS. 8-10) to provide individual packaged electronic devices 1100 as shown in FIGS. 11-11B.

FIGS. 12-12B show another example QFN electronic device 1200 and FIG. 12C shows an example method 1220 for fabricating an electronic device. The electronic device 1200 in FIGS. 12-12B includes structures, features, and dimensions 101-109 and 111-114, 116, and 118 corresponding to those described above in connection with FIGS. 1-1C. In this example, the electronic device 1200 includes first conductive features 109 at the corners 113, for example, tic bars that extend to and are contiguous with the die attach pad 114, and metal plate second conductive features 110 to provide an enhanced corner pad structure to facilitate good board level reliability. In one implementation, the second conductive features 110 are formed as metal plates, for example, using a second lead frame installed during fabrication processing (e.g., before molding, such as after die attach and wirebonding processes).

In addition, the electronic device 1200 in FIGS. 12-12B includes one or more rivets 1202 that attach a respective instance of the second conductive feature 110 to the instance of the first conductive feature 109 proximate each respective corner 113. In the illustrated example, to rivets 1202 are provided at each corner 113 to provide secure contacting attachment of the second conductive feature 110 to the first conductive feature 109. FIG. 12B shows a partial sectional side view taken along line 12B-12B of FIG. 12A, illustrating the attachment of the metal plate second conductive feature 110 to a portion of the tie bar first conductive feature 109 in the illustrated corner 113 of the electronic device 1200. As shown in FIG. 12B, and one example, the bottoms of the rivets 1202 can extend beyond the plane of the bottom or first side 101 of the electronic device 1200, and the riveting process and tooling used to form the rivets 1202 can be tailored to provide substantially flat bottoms of the rivets 1202, for example, to facilitate soldering of the second conductive feature 110 and the rivets 1202 to a conductive pad of a host printed circuit board, if desired by an end user.

As described above, an instance of the first conductive feature 109 in the electronic device 1200 is partially exposed outside the package structure 108 at each of the corners 113. As with the dual lead frame example of FIGS. 1-1B, the size and position of the second conductive features 110 are not restricted by lead frame fabrication process limitations, for example, to facilitate good board level reliability of the finished electronic device 1200. The instances of the second conductive feature 110 in the electronic device 1200 at each respective corner 113 are spaced apart from a nearest neighboring one of the conductive leads 107 by the first spacing distance 111 (e.g., FIGS. 12 and 12A) along each respective lateral side 103-106. The adjacent ones of the conductive leads 107 are spaced apart from one another along each respective lateral side 103-106 by a second spacing distance 112, and the first spacing distance 111 is less than the second spacing distance 112.

FIG. 12C shows another example method 1210 for making an electronic device such as the electronic device 1200 in FIGS. 12-12B. The method 1210 includes providing a first lead frame at 1201, such as the above described first lead frame 302 in FIG. 3 above. At 1212, die attach processing is performed, for example, to attach the semiconductor die 116 to the die attach pad 114 in each unit area 304 of the starting first lead frame 302 (e.g., FIG. 4 above). The method 1210 also includes wire bonding or other electrical connection processing at 1214, for example, to form the bond wires 118 to interconnect the semiconductor die 116 with one or more of the conductive leads 107 in each unit area 304 of the first lead frame panel array 302 (e.g., FIG. 5 above).

At 1216 in FIG. 12C, a second lead frame is secured or otherwise attached to (e.g., on) the first lead frame using a riveting process and tooling (not shown) to provide the instances of the second conductive features 110 attached by one or more rivets 1202 to the corresponding first conductive feature 109 in each prospective corner area. Attachment by vacuum or other fixtures can provide contacting arrangement of the conductive features 110 and 109 through molding operations. The use of rivets 1202 at 1216 helps mitigate the risk of lead frame wrinkling, particularly for thin lead frames (e.g., approximately 4 mil thick copper). The riveting attachment of the two lead frames can be done at any suitable point in the manufacturing process prior to molding operations, for example, and can be performed prior to die attach processing at 1212 and/or before wirebonding at 1214 in various different implementations, for instance, during lead frame manufacturing.

As shown in FIG. 12B, the riveting process at 1216 secures the second conductive feature 110 of a second lead frame in contact with the tie bar first conductive feature 109 of the first lead frame. In the illustrated example, the second lead frame is installed partially in contact with the back or bottom side of the first lead frame with portions of an instance of a second conductive feature 110 contacting a portion of the tie bar first conductive feature 109 in each corner area in each unit area of the first lead frame.

A molding process is performed at 1218 in FIG. 12C to form the molded package structure (e.g., 108 in FIG. 7 above). The method 1210 also includes package separation at 1220 and 1222 with column and row direction separation processing, respectively. In one example, the separation processing at 1220 and 1222 is the same as the processing at 210 and 212 in FIG. 2 as described above (e.g., FIGS. 8-10) to provide individual packaged electronic devices 1200 as shown in FIGS. 12-12B.

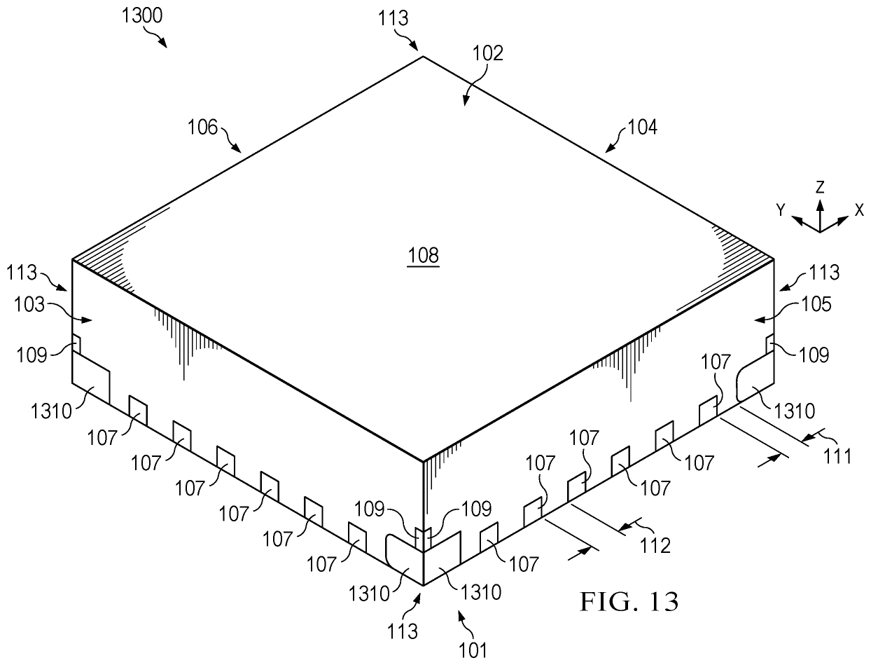

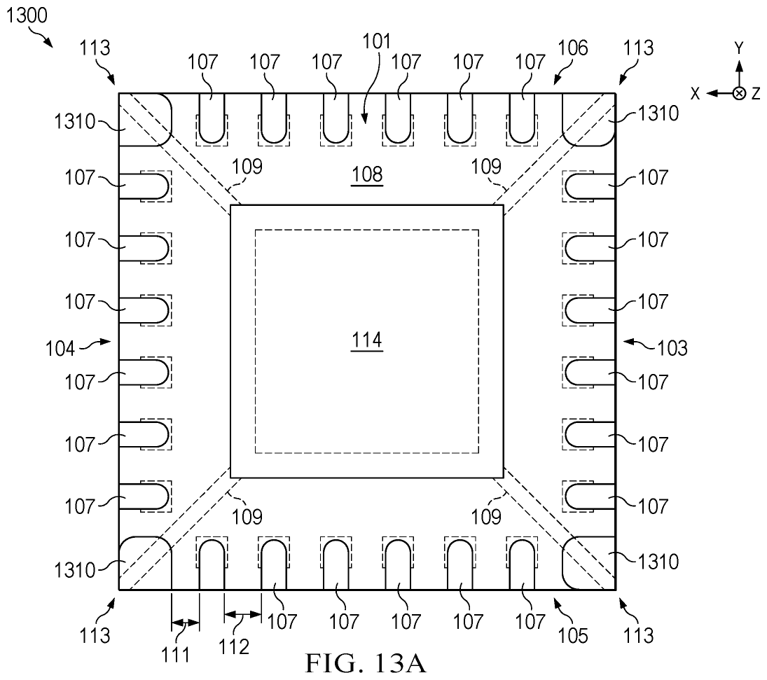

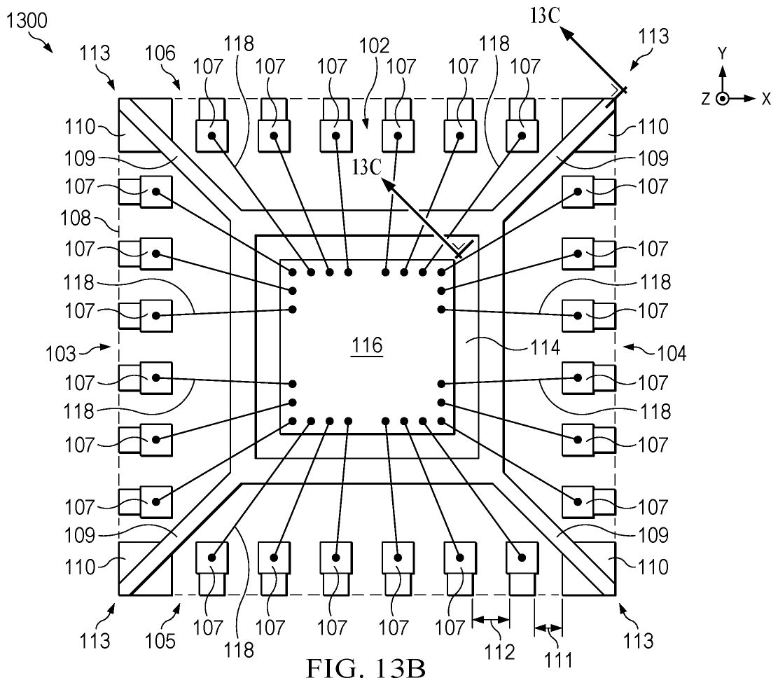

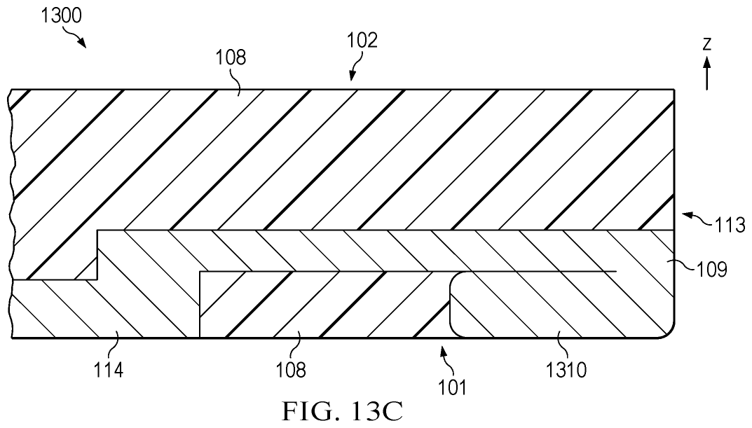

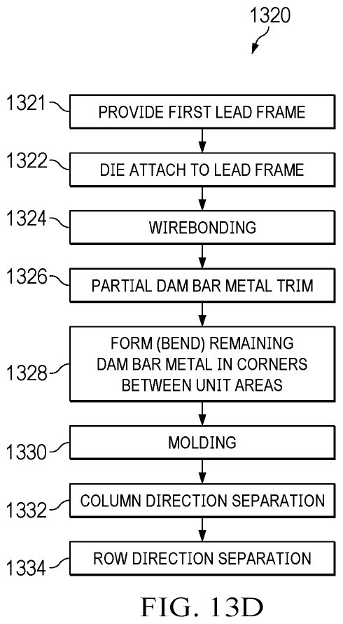

FIGS. 13-13C show another example QFN electronic device 1300 and FIG. 13D shows an example method 1320 for fabricating an electronic device. The electronic device 1300 in FIGS. 13-13C includes structures, features, and dimensions 101-109 and 111-114, 116, and 118 corresponding to those described above in connection with FIGS. 1-1C. FIG. 13 shows a top perspective view, FIG. 13A shows a bottom view, FIG. 13B shows a top view, and FIG. 13C shows a partial sectional side view of the electronic device 1300 taken along line 13C-13C of FIG. 13B. In this example, the electronic device 1300 includes first conductive features 109 at the corners 113, for example, tie bars that extend to and are contiguous with the die attach pad 114, and second conductive features 1310 that are at least partially bent from starting material of a first lead frame to provide an enhanced corner pad structure to facilitate good board level reliability.

As described above, an instance of the first conductive feature 109 in the electronic device 1300 is partially exposed outside the package structure 108 at each of the corners 113. In the example electronic device 1300 of FIGS. 13-13C, an instance of a second conductive feature 1310 includes bent or folded portion that is partially exposed outside the package structure 108 along the bottom or first side 101 at each of the corners 113.

FIG. 13D shows another example method 1320 for making an electronic device such as the electronic device 1300 of FIGS. 13-13C. The method 1320 includes providing a starting lead frame at 1321, such as the above described first lead frame 302 in FIG. 3. At 1322, die attach processing is performed, for example, to attach the semiconductor die 116 to the die attach pad 114 in each unit area 304 of the starting first lead frame 302 (e.g., FIG. 4 above). The method 1320 also includes wire bonding or other electrical connection processing at 1324, for example, to form the bond wires 118 to interconnect the semiconductor die 116 with one or more of the conductive leads 107 in each unit area 304 of the starting lead frame 302 (e.g., FIG. 5 above).

At 1326 in FIG. 13D, the method 1320 further includes partial dam bar metal trimming, for example using punches or other suitable cutting or trimming equipment (not shown) to trim or otherwise remove dam bar sections that intersect the row and column direction saw streets between adjacent unit areas of the lead frame panel array 302. This operation leaves the remaining dam bar material and connected tie bars 109 allowing for subsequent forming operations.

The method 1320 in this example continues at 1328 with forming the remaining dam bar metal in the corners between unit areas of the lead frame panel array 302. In one example, the forming operations at 1328 include bending and/or folding, such as using suitable forming dies and fixtures (not shown) that fold the separated dam bar material underneath the corridor portions of the tie bar first conductive features 109, for example, as shown in FIG. 13C. In this example, the instances of first conductive feature 109 and the second conductive feature 1310 at each respective corner 113 are contiguous and a portion of the instance of the second conductive feature 1310 is folded under a portion of the instance of the first conductive feature 109 at each respective corner 113. The folded or underlying portion 1310 in this example forms the second conductive feature in contact with the first conductive feature 109 at each corner 113 of the electronic device 1300, and the bottom side of the folded second conductive feature 1310 extends in one example approximately coplanar with the bottom or first side 101 of the electronic device 1310, although coplanar the is not a strict requirement of all possible implementations. In another implementation (not shown), the forming process at 1328 partially folds or bends some of the starting metal to form the second conductive feature 1310, which remains contiguous with the first conductive feature 109, but need not be folded completely to contact the bottom side of the first conductive feature 109.

The method 1320 continues at 1330 in FIG. 13D with a molding process that forms the molded package structure (e.g., 108 in FIG. 7 above). The method 1320 in FIG. 13D continues at 1332 and 1334 with column and row direction separation processing, respectively. In one example, the separation processing at 1332 and 1334 is the same as the processing at 210 and 212 in FIG. 2 as described above (e.g., FIGS. 8-10) to provide individual packaged electronic devices 1300 as shown in FIGS. 13-13C. The dam bar portion can be folded at 1328 after the partial trimming at 1326 to form the corner pads (either bottom pads or side wall pads) in the finished device. Unlike the examples above, the corner pad size depends on the tie bar dimensions and is not completely independent of the manufacturing process used in fabricating the initial starting lead frame 302.

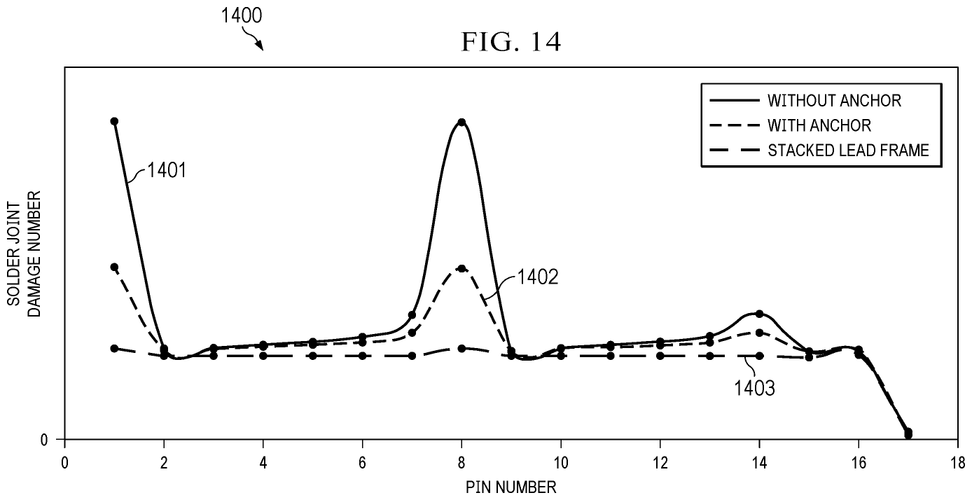

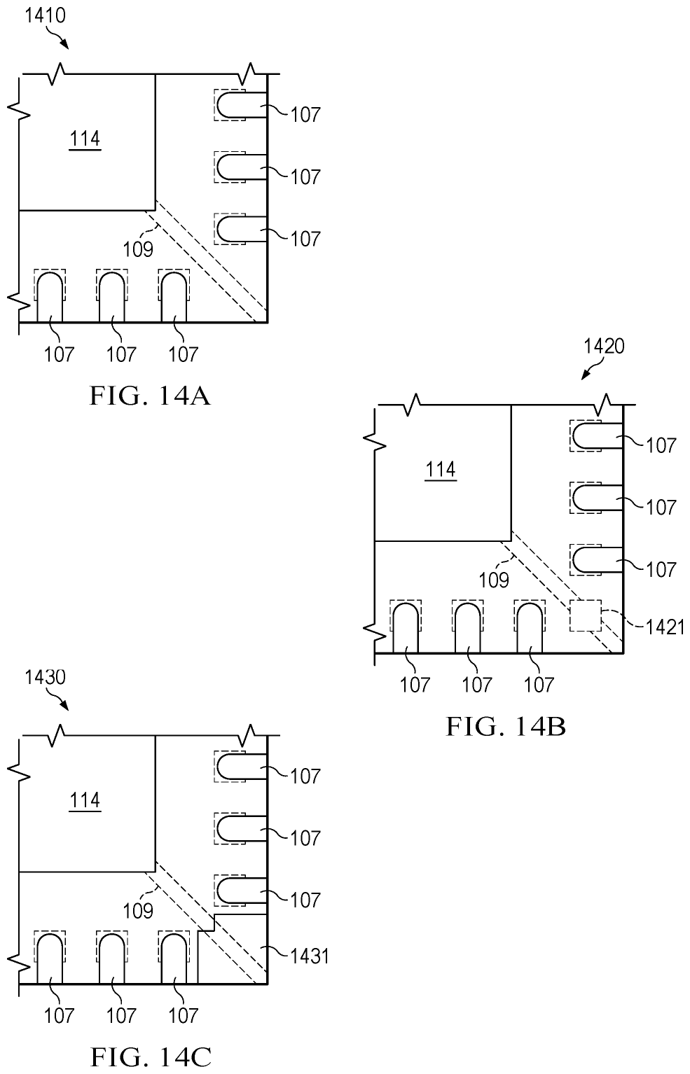

Referring also to FIGS. 14-14C, FIG. 14 shows a graph 1400 with solder joint damage number curves 1401, 1402, and 1403 that show comparative simulated solder joint damage for different pins of different modeled QFN electronic devices. FIG. 14A shows a lower right quadrant of a first modeled QFN electronic device 1410 with a tie bar 109 that extends to a corner 113, with no anchoring structure such as a dummy pad of the initial starting lead frame and no additional second conductive feature providing an anchoring structure in the device corner. The curve 1401 in FIG. 14 shows the relatively high solder joint damage of this simulated implementation, particularly for an pins (e.g., pin number 1, pin number 8, etc.).

FIG. 14B shows a similar quadrant of a second modeled QFN electronic device 1420 with the tie bar 109 extending to the corner 113, as well as an integral dummy pad 1421 formed as part of the starting lead frame. The curve 1402 in FIG. 14 corresponds to the simulated solder joint damage number for the model the electronic device 1420 of FIG. 14B. The addition of the dummy pad structure 1421 as part of the tie bar 109 near the corner 113 helps to reduce the solder joint damage number compared with the simulated solder joint damage number of the QFN device model 1410 of FIG. 14A. However, as discussed previously, this approach is limited by manufacturing tolerances and process limitations associated with fabricating the starting lead frame.

FIG. 14C shows a comparative quadrant of a modeled QFN electronic device 1430 that corresponds to the electronic device 100 of FIGS. 1-1C above, using a second lead frame during manufacturing to create a second conductive feature 1431 originally formed as part of the second lead frame and held in contacting relationship with a portion of the overlying tie bar first conductive metal structure 109. The curve 1403 in the graph 1400 of FIG. 14 shows the simulated solder joint damage number results for the modeled electronic device 1430 of FIG. 14C, which provides significant reduction in the solder joint damage resulting from thermal and/or mechanical stresses to the respective electronic devices compared with the results shown in the curve 1401 and 1402.

The simulation and modeling of FIGS. 14-14C correspond to a 64 pin QFN package design with approximately 9×9×0.9 mm dimensions and a 0.5 mm pitch between adjacent leads along a given one of the lateral sides, using a die size of approximately 6×6 mm. The simulated conditions include soldered attachment to a 1.6 mm thick host printed circuit board (not shown), undergoing thermal cycling from −40° C. to +125° C. using 60 Minutes per cycle, and the indicated pin number 17 in the graph 1400 corresponds to a device thermal pad, such as the exposed bottom side of the die attach pad 114 in FIGS. 1-1C. The simulated solder joint damage number represented by the curves 1401-1403 represents the number that indicates higher risk for solder joint cracking and earlier board level reliability degradation. In addition to the significant reduction in the end or corner pin (lead) solder joint damage, the second conductive features of the illustrated examples also provide benefits with respect to interior or non-end/corner conductive leads of the electronic device 100.

Modifications are possible in the described examples, and other implementations are possible, within the scope of the claims.

What is claimed is:

1. An electronic device, comprising:
a package structure having opposite first and second sides, four lateral sides, and four lateral corners;
a semiconductor die at least partially enclosed inside the package structure and attached to a die attach pad;
conductive leads at least partially exposed outside the package structure along the four lateral sides, a first one of the conductive leads electrically connected to the semiconductor die;
an instance of a first conductive feature partially exposed outside the package structure at each of the corners; and
an instance of a second conductive feature partially exposed outside the package structure along the first side and contacting a respective instance of the first conductive feature at each of the corners.

2. The electronic device of claim 1, wherein the instance of the second conductive feature at each respective corner is exposed outside the package structure along portions of two respective ones of the lateral sides at that respective corner.

3. The electronic device of claim 2, wherein:
the instance of the second conductive feature at each respective corner is spaced apart from a nearest one of the conductive leads along each respective lateral side by a first spacing distance;
adjacent ones of the conductive leads are spaced apart from one another along each respective lateral side by a second spacing distance; and
the first spacing distance is less than the second spacing distance.

4. The electronic device of claim 1, wherein:
the instance of the second conductive feature at each respective corner is spaced apart from a nearest one of the conductive leads along each respective lateral side by a first spacing distance;
adjacent ones of the conductive leads are spaced apart from one another along each respective lateral side by a second spacing distance; and
the first spacing distance is less than the second spacing distance.

5. The electronic device of claim 1, wherein the instance of the first conductive feature at each respective corner is contiguous with the die attach pad.

6. The electronic device of claim 5, wherein the instance of the second conductive feature at each respective corner is a metal pad.

7. The electronic device of claim 6, comprising a rivet that attaches the instance of the second conductive feature to the instance of the first conductive feature proximate each respective corner.

8. The electronic device of claim 5, comprising a rivet that attaches the instance of the second conductive feature to the instance of the first conductive feature proximate each respective corner.

9. The electronic device of claim 5, wherein:
the instances of first conductive feature and the second conductive feature at each respective corner are contiguous; and
a portion of the instance of the second conductive feature is folded under a portion of the instance of the first conductive feature at each respective corner.

10. The electronic device of claim 1, wherein:
the instance of the second conductive feature at each respective corner is spaced apart from a nearest one of the conductive leads along each respective lateral side by a first spacing distance;
adjacent ones of the conductive leads are spaced apart from one another along each respective lateral side by a second spacing distance; and
the first spacing distance is less than the second spacing distance.

11. The electronic device of claim 1, comprising a rivet that attaches the instance of the second conductive feature to the instance of the first conductive feature proximate each respective corner.

12. The electronic device of claim 1, wherein:
the instances of first conductive feature and the second conductive feature at each respective corner are contiguous; and
a portion of the instance of the second conductive feature is folded under a portion of the instance of the first conductive feature at each respective corner.

13. An electronic device, comprising:
a package structure having opposite first and second sides, four lateral sides, and four lateral corners;
a semiconductor die at least partially enclosed inside the package structure and attached to a die attach pad;
conductive leads at least partially exposed outside the package structure along the four lateral sides, a first one of the conductive leads electrically connected to the semiconductor die;
an instance of a first conductive feature partially exposed outside the package structure at each of the corners; and
an instance of a second conductive feature including a conductive film partially exposed outside the package structure along the first side at each of the corners.

14. The electronic device of claim 13, wherein the instance of the second conductive feature at each respective corner is exposed outside the package structure along portions of two respective ones of the lateral sides at that respective corner.

15. The electronic device of claim 13, wherein:
the instance of the second conductive feature at each respective corner is spaced apart from a nearest one of the conductive leads along each respective lateral side by a first spacing distance;
adjacent ones of the conductive leads are spaced apart from one another along each respective lateral side by a second spacing distance; and
the first spacing distance is less than the second spacing distance.

16. The electronic device of claim 13, wherein the instance of the first conductive feature at each respective corner is contiguous with the die attach pad.

17. A method of fabricating an electronic device, the method comprising:
providing a conductive metal lead frame with rows and columns of unit areas, each unit area joined to a neighboring unit area of an adjacent row or column, each unit area having a die attach pad and four corner areas that include a respective instance of a first conductive feature;
attaching a semiconductor die to the die attach pad in each unit area;
forming an instance of a package structure that encloses the semiconductor die and has opposite first and second sides, four lateral sides, and four lateral corners in each unit area;
forming an instance of a second conductive feature partially exposed outside the first side of the package structure at each of the corners in each unit area; and
separating the electronic device from the lead frame.

18. The method of claim 17, wherein:
the conductive metal lead frame is a first lead frame; and
forming the instances of the second conductive feature includes securing a second lead frame to the first lead frame, the second lead frame having an instance of a second conductive feature contacting each corner area in each unit area of the first lead frame.

19. The method of claim 17, wherein forming the instances of the second conductive feature includes forming a conductive film on the first side of the package structure near the lateral corners in each unit area.

20. The method of claim 17, wherein forming the instances of the second conductive feature includes bending a portion of the lead frame under each respective instance of a first conductive feature.
